(19) United States
(12) Patent Application Publication
(10) Pub. No.: US 2026/0266889 A1
(43) Pub. Date: Sep. 10, 2026

(54) METHOD AND SYSTEM FOR ANALYZING DEFECTS OF LIGHT EMITTING DEVICES

(71) Applicants: Samsung Display Co., Ltd., Yongin-si (KR); POSTECH Research and Business Development Foundation, Pohang-si (KR)

(72) Inventors: Jong Kyu KIM, Pohang-si (KR); Jeonghyeon PARK, Pohang-si (KR); Chul Jong YOO, Yongin-si (KR); Buem Joon KIM, Yongin-si (KR); Jawon KIM, Pohang-si (KR); Jun Seok JEONG, Yongin-si (KR)

(21) Appl. No.: 19/405,795

(22) Filed: Dec. 2, 2025

(30) Foreign Application Priority Data
Mar. 5, 2025 (KR) 10-2025-0027976

(51) Int. Cl. G01R 31/26

(52) U.S. Cl. CPC G01R 31/2635

(57) ABSTRACT

Provided are method and system for analyzing defects of light emitting devices. According to various embodiments of the present disclosure, a method for analyzing defects of light emitting devices includes: injecting a current into each of N light emitting devices having different sizes at M different temperatures, measuring a photocurrent according to the injected current, and deriving a plurality of data; distinguishing and deriving a bulk defect factor and M×N surface defect factors from each other from the plurality of data; and deriving a first defect concentration for the bulk defect factor and N second defect concentrations for the M×N surface defect factors, wherein M is a natural number of 2 or more, and N is a natural number of 2 or more.

### CROSS-REFERENCE TO RELATED APPLICATION

The present application claims priority to and the benefit of Korean Patent Application No. 10-2025-0027976, filed on Mar. 5, 2025, in the Korean Intellectual Property Office, the entire disclosure of which is incorporated herein by reference.

### STATEMENT REGARDING PRIOR DISCLOSURE BY THE INVENTORS UNDER 37 CFR § 1.77(b)(6)

The subject matter disclosed in the publication titled “Quantitative Analysis and Characterization of Sidewall Defects in InGaN-Based Blue Micro-LEDs” published on Oct. 31, 2024, by authors including the inventors of the present application, incorporates a public disclosure relating to the disclosure of the present application under 35 U.S.C. 102(b)(1)(B).

### BACKGROUND

### 1. Field

One or more aspects of embodiments of the present disclosure are directed to a method and system for analyzing defects of light emitting devices.

### 2. Description of the Related Art

In the field of light emitting devices, III-V nitride semiconductors such as GaN have attracted attention because of their applicability as light emitting diodes (LEDs) and/or laser diodes (LDs) due to their excellent physical and chemical properties. The LEDs and/or the LDs using III-V nitride semiconductor materials have been widely used to emit ultraviolet (UV), blue, and/or green light, and such light emitting devices have been widely applied in various fields. For example, due to their efficiency, the III-V nitride semiconductor materials have been widely used in light emitting diodes using InGaN/GaN multiple quantum wells (MQWs) structures. Such light emitting diodes may be utilized in various optoelectronic device applications such as semiconductor illumination, LCD backlights, full-color displays, traffic lights, and/or indicator lights. Light sources using such light emitting diodes will be used to expand the scope of our environment, and to this end, it is desired or required to develop high-efficiency light emitting diode light sources that produce higher (e.g., brighter) light with lower (reduced) power consumption.

Light emitting characteristics of the light emitting devices such as the LEDs are determined by a rate at which injected charges are converted into photons within an active layer and emitted to the outside. For example, external quantum efficiency (EQE) of the light emitting device described above may be determined by internal quantum efficiency (IQE) indicating a rate at which the injected charges are converted into the photons within the active layer and light extraction efficiency (LEE) indicating a rate at which photons internally generated by converting an emission wavelength are extracted to the outside.

As the demand for LEDs having a small size to be used as light sources for next-generation displays such as displays for virtual reality (VR)/augmented reality (AR) has increased, an efficiency drop phenomenon in which efficiency of the LED itself drops as the size of the LED decreases has been observed. The phenomenon is believed to be mainly due to an increase in a nonradiative recombination on a surface as a ratio of a surface area to a total volume increases due to the decrease in size, and such phenomenon has become a major obstacle to LED performance.

In order to determine and overcome a cause of the efficiency drop phenomenon in which the efficiency of the light emitting device drops as the size of the light emitting device decreases, the internal quantum efficiency needs to be directly measured. These measurements can help locate sources (or causes) of a nonradiative recombination phenomenon that may occur in a recombination process of positive charges and negative charges.

### SUMMARY

Aspects of embodiments of the present disclosure provide a method and system for analyzing a cause of a nonradiative recombination in which a first carrier and a second carrier recombine with each other but light is not emitted.

However, aspects of the present disclosure are not restricted to those set forth herein. The above and other aspects of the present disclosure will become more apparent to one of ordinary skill in the art to which the present disclosure pertains by referencing the detailed description of the present disclosure given herein below.

A method for analyzing defects of light emitting devices includes injecting a current into each of N light emitting devices having different sizes at M different temperatures, measuring a photocurrent according to the injected current, and deriving a plurality of data; distinguishing and deriving a bulk defect factor and M×N surface defect factors from each other from the plurality of data; and, deriving a first defect concentration for the bulk defect factor and N second defect concentrations for the M×N surface defect factors, wherein M is a natural number of 2 or more, and N is a natural number of 2 or more.

A system for analyzing defects of light emitting devices includes: a data preprocessing unit performing to perform an operation of injecting a current into each of N light emitting devices having different sizes at M different temperatures, measuring a photocurrent according to the injected current, and deriving a plurality of data; a first analysis unit to performing an operation of distinguishing and deriving a bulk defect factor and M×N surface defect factors from each other from the plurality of data; and a second analysis unit to performing an operation of deriving a first defect concentration for the bulk defect factor and N second defect concentrations for the M×N surface defect factors, wherein M is a natural number of 2 or more, and N is a natural number of 2 or more.

A method and system for analyzing a cause of a nonradiative recombination in which a first carrier and a second carrier recombine with each other but light is not emitted may be provided.

A defect acting as a cause (e.g., main cause) of the nonradiative recombination may be analyzed by the method and/or system provided in the present disclosure.

A quantitative analysis of factor(s) affecting light emitting efficiency of a light emitting device may be performed by utilizing the defect analyzed using the method and/or system provided in the present disclosure. Accordingly, the light emitting efficiency of the light emitting device may be improved by the method and system according to the present embodiments.

### BRIEF DESCRIPTION OF THE DRAWINGS

The above and other aspects and features of the present disclosure will become more apparent by describing in more detail embodiments thereof with reference to the attached drawings, in which:

FIG. 1 is a view for describing aspects of recombinations appearing in a light emitting device to which a current is applied;

FIG. 2 is a view for describing a type or kind of defect appearing in a first nonradiative recombination;

FIGS. 3-5 are each a flowchart for describing a method for analyzing defects of light emitting devices according to one or more embodiments of the present disclosure;

FIG. 6 is a view for describing distinguishing a bulk defect factor and a surface defect factor from each other;

FIGS. 7-13 are views for describing deriving a defect concentration for the bulk defect factor and a defect concentration for the surface defect factor; and

FIG. 14 is a block diagram illustrating a measuring device that may be used in an operation or a process of measuring a current injected into a light emitting device and a photocurrent according to the injected current.

### DETAILED DESCRIPTION

The advantages and features of the embodiments disclosed herein, and methods of achieving them, will become apparent upon reference to the embodiments described in more detail with accompanying drawings. However, the present disclosure is not limited to the embodiments disclosed herein, but will be embodied in many different forms, and these embodiments are provided merely to make the disclosure complete and to fully inform one of ordinary skill in the art to which the invention according to the present disclosure belongs, and the invention according to the present disclosure is defined by the scope of the claims.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Throughout this specification, like reference numerals refer to like components. The shapes, sizes, proportions, angles, numbers, and/or the like disclosed in the drawings to illustrate embodiments are just examples and are not intended to be limiting to those shown herein.

Although the terms “first”, “second”, and/or the like are used to describe various components, the components are not limited by these terms. Thus, a first component referred to herein may also be a second component within the technical idea of the present invention.

Each of the features of the one or more embodiments disclosed herein may be combined or combinable with each other, in part or in whole, and may be technically interlocked and operated in a variety of ways, and each embodiment may be practiced independently of or in conjunction with one another.

As used herein, the singular forms “a,” “an,” and “the” are intended to include the plural forms as well, unless the context clearly indicates otherwise.

It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Specific embodiments will be described below with reference to the accompanying drawings. Configurations that function substantially the same between embodiments are given the same drawing designation and repeated descriptions are not provided.

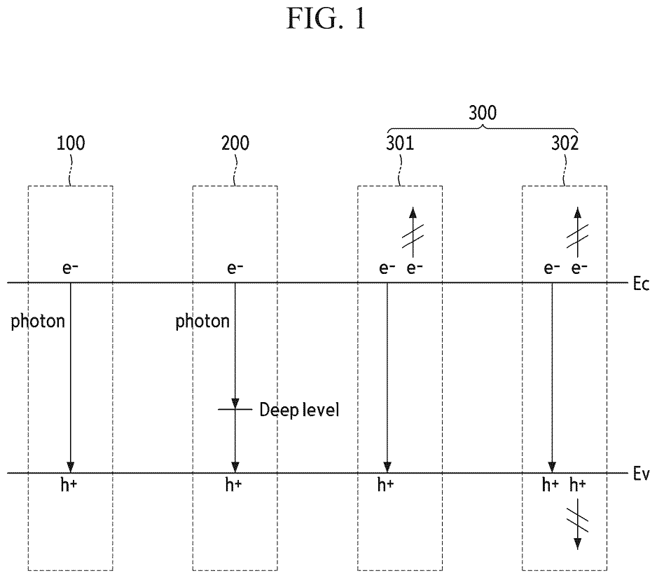

FIG. 1 is a view for describing aspects of recombinations appearing in a light emitting device to which a current is applied.

Referring to FIG. 1, if (e.g., when) a current is injected into or applied to a light emitting device, a first carrier e− may be injected in a first energy state Ec, and a second carrier h+ may be injected in a second energy state Ev. In one or more embodiments, the first carrier e− may be a negative charge (e.g., an electron), and the second carrier h+ may be a positive charge (e.g., a hole), but embodiments of the present disclosure are not limited thereto.

The first carrier e− may change from the first energy state Ec to the second energy state Ev, and the first carrier e− may combine with the second carrier h+ in the second energy state Ev. When the first carrier e− injected in the first energy state Ec and the second carrier h+ injected in the second energy state Ev combine with each other in the second energy state Ev, an exciton is formed, and a photon corresponding to a difference between an energy level corresponding to the first energy state Ec and an energy level corresponding to the second energy state Ev is generated. A phenomenon in which the first carrier e− and the second carrier h+ combine with each other is expressed as a recombination. Such a photon may be observed as light from the outside. Here, the difference between the energy level corresponding to the first energy state Ec and the energy level corresponding to the second energy state Ev is defined as E=hv (where h is a Planck's constant and v is a frequency), and v (frequency) corresponds to a value obtained by dividing a speed of light by a wavelength of light.

When a case where the first carrier e− and the second carrier h+ generally recombine with each other appears as an aspect of a first recombination 100, the light may be observed as described above. The first recombination 100 is expressed as an emission recombination, and is a case where when the first carrier e− in the first energy state Ec loses energy and transitions to the second energy state Ev, as much energy as the difference between the energy level corresponding to the first energy state Ec and the energy level corresponding to the second energy state Ev is emitted in the form of light.

However, the recombination may not be realized only as the light due to one or more suitable factors. A case where the first carrier e− and the second carrier h+ recombine with each other may include a second recombination 200 (or a first nonradiative recombination) and a third recombination 300 (or a second nonradiative recombination) in addition to the first recombination 100.

The second recombination 200 (or the first nonradiative recombination) and the third recombination 300 (or the second nonradiative recombination) may be expressed (or may be referred to) as nonradiative recombinations. Accordingly, aspects of the nonradiative recombinations may appear as the second recombination 200 (or the first nonradiative recombination) and the third recombination 300 (or the second nonradiative recombination).

When the nonradiative recombination appears as the aspect of the second recombination 200 (or the first nonradiative recombination), an energy level of the first carrier e− does not directly change from the first energy state Ec to the second energy state Ev while the first carrier e− recombines with the second carrier h+. For example, the energy level of the first carrier e− directly changes to the second energy state Ev in the first recombination 100, but does not directly change to the second energy state Ev in the second recombination 200 (or the first nonradiative recombination).

In the second recombination 200 (or the first nonradiative recombination), the first carrier e− changes to the second energy state Ev via a defect level Deep level existing in the middle (or substantially in the middle). When the nonradiative recombination appears as the aspect of the second recombination 200 (or the first nonradiative recombination), as much energy as the difference between the energy level corresponding to the first energy state Ec and the energy level corresponding to the second energy state Ev may be emitted in the form of a phonon, e.g., heat, rather than the light. The nonradiative recombination corresponding to the second recombination 200 (or the first nonradiative recombination) may be expressed (or may be referred to) as a Shockley-Read-Hall recombination.

In the third recombination 300 (or the second nonradiative recombination), when the first carrier e− changes to the second energy state Ev, as much energy as the difference between the energy level corresponding to the first energy state Ec and the energy level corresponding to the second energy state Ev may be transferred to another first carrier e− 301 and/or transferred to the second carrier h+302. When the nonradiative recombination appears as the aspect of the third recombination 300 (or the second nonradiative recombination), the first carrier e− and the second carrier h+ recombine with each other, but as much energy as the difference between the energy level corresponding to the first energy state Ec and the energy level corresponding to the second energy state Ev may be transferred to another carrier (the first carrier e− or the second carrier h+) rather than the light. The nonradiative recombination corresponding to the third recombination 300 (or the second nonradiative recombination) may be expressed (or may be referred to) as an Auger recombination.

In a process in which the first carrier e− and the second carrier h+ recombine with each other, an emission recombination phenomenon including the first recombination 100 occurs, such that the light may be generated, but a nonradiative recombination phenomenon including the second recombination 200 (or the first nonradiative recombination) and the third recombination 300 (or the second nonradiative recombination) may also occur, such that the light may not be generated.

The present disclosure may provide a method and system for analyzing a cause of a nonradiative recombination in which the first carrier e− and the second carrier h+ recombine with each other but the light is not emitted. A defect acting as a cause (e.g., a main cause) of the nonradiative recombination may be analyzed by the method and/or system provided in the present disclosure. A quantitative analysis of the factors affecting light emitting efficiency of a light emitting device may be performed by utilizing the defect analyzed using the method and/or system provided in the present disclosure. Accordingly, the light emitting efficiency of the light emitting device may be improved by the method and system.

In particular, a method and system for quantitatively analyzing a cause of the first nonradiative recombination of a plurality of nonradiative recombination aspects are provided in the present disclosure.

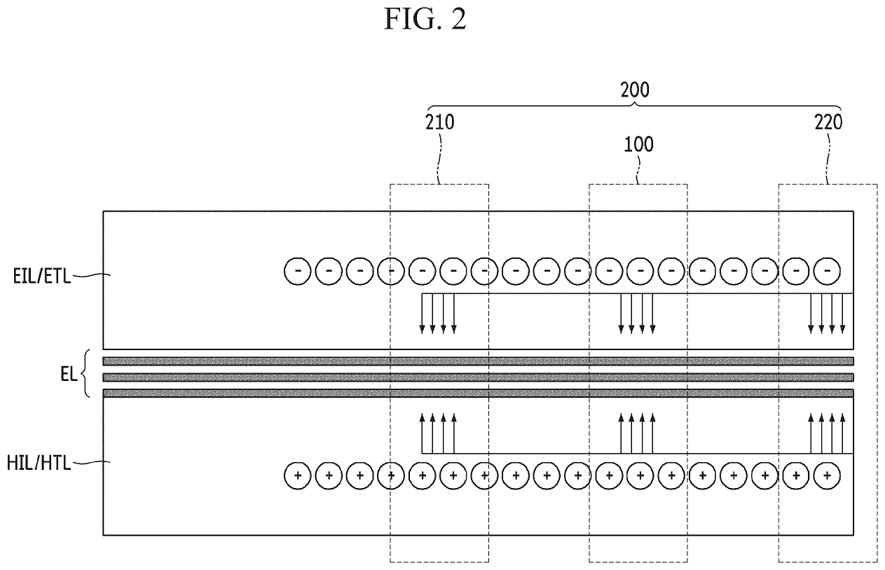

FIG. 2 is a view for describing a type or kind of defect appearing in a first nonradiative recombination.

Referring to FIG. 2, the first nonradiative recombination 200 may be caused by a plurality of defects. The first recombination 100 refers to a case where the first carrier passing through an electron injecting layer/transporting layer EIL/ETL and the second carrier passing through a hole injecting layer/transporting layer HIL/HTL recombine with each other in a light emitting layer EL to emit light. The first nonradiative recombination 200 is a recombination that does not emit the light, and may be caused by a bulk defect 210 and a surface defect 220. A plurality of defects including the bulk defect 210 and the surface defect 220 may exist inside a light emitting device.

For example, the plurality of defects may be divided into the bulk defect 210 that may occur during the growth of the hole injecting layer/transporting layer HIL/HTL, the electron injecting layer/transporting layer EIL/ETL, and/or the light emitting layer EL, and the surface defect 220 that may occur in an etching process during the light emitting device manufacturing processes.

The present disclosure may provide a method for analyzing the plurality of defects that are causes of the first nonradiative recombination 200. The present disclosure provides a method for quantitatively analyzing the bulk defect 210 and the surface defect 220 that are the causes of the first nonradiative recombination 200. When the method disclosed in the present disclosure is used, it is possible to determine which of the surface defect 220 and the bulk defect 210 is a dominant defect causing the first nonradiative recombination 200 as the size of the light emitting device decreases or increases.

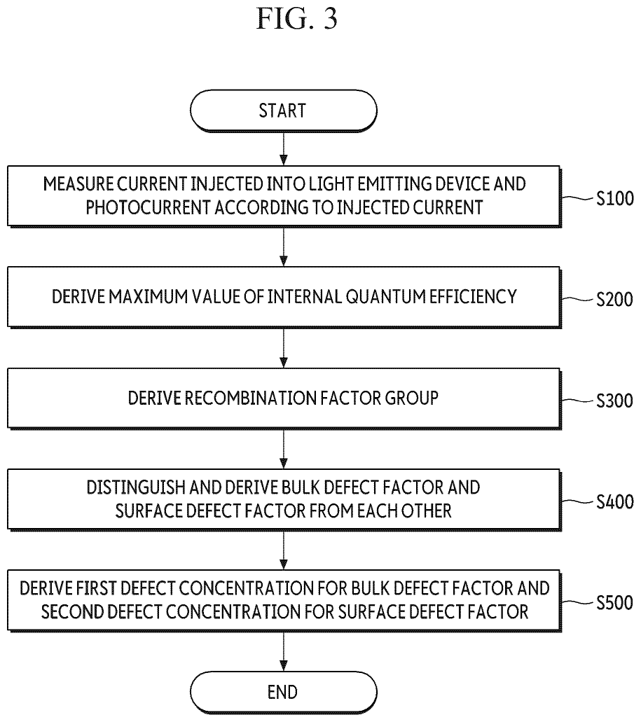

FIGS. 3 to 5 are flowcharts for describing a method for analyzing defects of light emitting devices according to one or more embodiments of the present disclosure.

Referring to FIG. 3, the method for analyzing defects of light emitting devices according to one or more embodiments of the present disclosure may include injecting a current into each of N light emitting devices having different sizes at M different temperatures and measuring a photocurrent according to the injected current (S100), deriving maximum value of internal quantum efficiency (S200), and deriving a plurality of data including recombination factor group (S300), distinguishing and deriving a bulk defect factor and M×N surface defect factors from each other from the plurality of data (S400), and deriving a first defect concentration for the bulk defect factor and N second defect concentrations for the M×N surface defect factors (S500). In one or more embodiments, M and N may be natural numbers of 2 or more.

A system for analyzing defects of light emitting devices according to one or more embodiments of the present disclosure may include a data preprocessing unit performing an operation of injecting a current into each of N light emitting devices having different sizes at M different temperatures, measuring a photocurrent according to the injected current, and deriving a plurality of data, a first analysis unit distinguishing and deriving a bulk defect factor and M×N surface defect factors from each other from the plurality of data, and a second analysis unit deriving a first defect concentration for the bulk defect factor and N second defect concentrations for the M×N surface defect factors.

Hereinafter, steps performed in the method for analyzing defects of light emitting devices and operations performed in the system for analyzing defects of light emitting devices will be described without distinction, but two categories are different from each other, with one being a method and another being a system. The system for analyzing defects of light emitting devices may include all objects (e.g., devices, equipment, and/or the like) specifically realized or provided by combining information processing of software implementing the method for analyzing defects of light emitting devices with hardware. The system for analyzing defects of light emitting devices may further include a memory capable of storing measured and/or processed data, a power module capable of driving the system, and/or the like.

A processor may include at least one selected from among a central processing unit (CPU), an application processor (AP), a graphic processing unit (GPU), a communication processor (CP), an image signal processor (ISP), and a controller.

The memory may store data information necessary or suitable for an operation of the processor and/or a display module. When the processor executes an application stored in the memory, an image data signal and/or an input control signal may be transmitted to the display module, and the display module may process a received signal and output image information through a display screen.

The power module may include a power supply module such as a power adapter and/or a battery device. The power module may include a power conversion module. The power conversion module may convert power supplied by the power supply module to generate power necessary or suitable for an operation of an electronic device.

When a current is injected into a light emitting device having a set or specific size at a set or specific temperature and a photocurrent is measured, set or specific data may be derived. The set or specific data may include a Q factor, a maximum value of internal quantum efficiency, and a recombination factor group for the light emitting device having the set or specific size at the set or specific temperature. The recombination factor group may include a first nonradiative recombination factor, an emission recombination factor, and a second nonradiative recombination factor.

Because the set or specific data is derived from the light emitting device having the set or specific size at the set or specific temperature, when the above steps are performed on all of the N light emitting devices having the different sizes at the M different temperatures, M×N set or specific data may be derived.

When the M×N set or specific data points are derived, a bulk defect factor and a surface defect factor may be distinguished and derived from each other from the M×N set or specific data, and a first defect concentration (e.g., defect concentration for the bulk defect factor) and a second defect concentration (e.g., defect concentration for the surface defect factor) may be derived by processing these data points. Accordingly, the present disclosure may provide a method and/or system for quantitatively analyzing defects of light emitting devices, and light emitting devices with increased light emitting efficiency may be provided by utilizing the method and/or system according to the present embodiments.

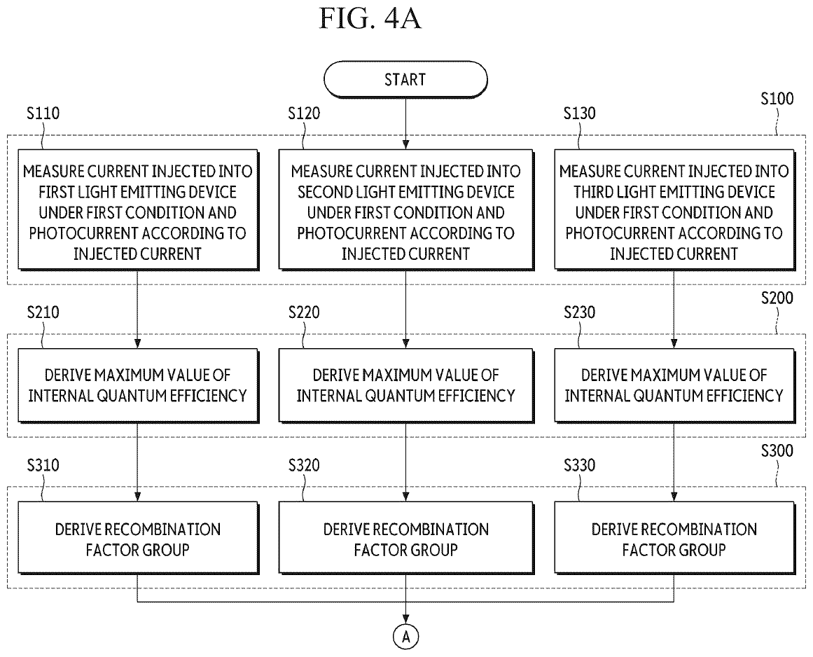

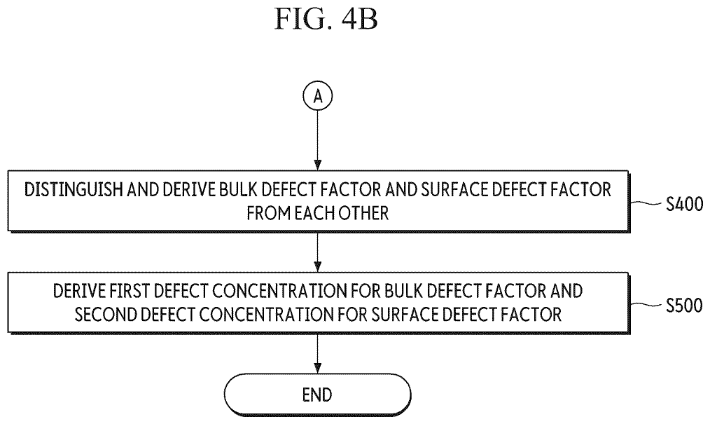

Referring to FIGS. 4A and 4B, currents injected into the N light emitting devices having the different sizes under the same condition (e.g., a first condition) and photocurrents according to the injected currents may be measured. For example, a first light emitting device may have a first diameter, a second light emitting device may have a second diameter, and a third light emitting device may have a third diameter. The first diameter may be smaller than the second diameter, and the second diameter may be smaller than the third diameter.

In one or more embodiments, N may be 3 in the N light emitting devices having the different sizes, but embodiments of the present disclosure are not limited thereto. Data under the same condition (e.g., the first condition) may be derived for all of such three types (kinds) of light emitting devices.

For example, the method for analyzing defects of N light emitting devices (where N is 3) may include: measuring current injected into the first light emitting device under the first condition and measuring a photocurrent according to the injected current (S110), measuring current injected into the second light emitting device under the first condition and measuring a photocurrent according to the injected current (S120), measuring current injected into the third light emitting device under the first condition and measuring a photocurrent according to the injected current (S130), deriving maximum value of internal quantum efficiency for the first light emitting device (S210), the second light emitting device (S220), and the third light emitting device (S230), and deriving a plurality of data including recombination factor group for the first light emitting device (S310), the second light emitting device (S320), and the third light emitting device (S330), as well as distinguishing and deriving a bulk defect factor and M×N surface defect factors from each other from the plurality of data (S400), and deriving a first defect concentration for the bulk defect factor and N second defect concentrations for the M×N surface defect factors (S500). Here, N=3 and M=1.

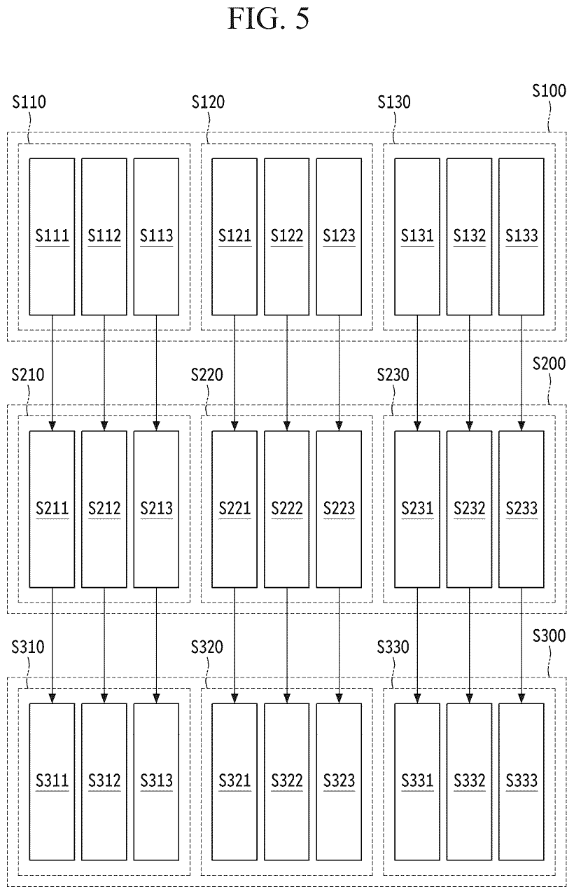

Referring to FIG. 5, the number of same conditions may be plural. For example, when a current injection and a photocurrent measurement according to the injected current are performed on each of the N light emitting devices having the different sizes at the M different temperatures, M×N measurements may be performed. For example, performing measurements on the N light emitting devices under the first condition (S111, S121, and S131), performing measurements on the N light emitting devices under a second condition (S112, S122, and S132), and performing measurements on the N light emitting devices under a third condition (S113, S123, and S133) may be performed, and in this case, M may be 3, but embodiments of the present disclosure are not limited thereto. Temperatures in the first condition, the second condition, and the third condition may all be different from each other.

In one or more embodiments, extracting data on the first light emitting device under the first condition (S111), extracting data on the first light emitting device under the second condition (S112), and extracting data on the first light emitting device under the third condition (S113) may be performed.

In one or more embodiments, extracting data on the second light emitting device under the first condition (S121), extracting data on the second light emitting device under the second condition (S122), and extracting data on the second light emitting device under the third condition (S123) may be performed.

In one or more embodiments, extracting data on the third light emitting device under the first condition (S131), extracting data on the third light emitting device under the second condition (S132), and extracting data on the third light emitting device under the third condition (S133) may be performed.

A Q factor, a maximum value of internal quantum efficiency, and a recombination factor group may be derived from each of the plurality of data points measured under each condition.

For example, deriving a maximum value of internal quantum efficiency from the data on the first light emitting device measured under the first condition (S211), deriving a maximum value of internal quantum efficiency from the data on the first light emitting device measured under the second condition (S212), and deriving a maximum value of internal quantum efficiency from the data on the first light emitting device measured under the third condition (S213) may be performed.

In addition, deriving a maximum value of internal quantum efficiency from the data on the second light emitting device measured under the first condition (S221), deriving a maximum value of internal quantum efficiency from the data on the second light emitting device measured under the second condition (S222), and deriving a maximum value of internal quantum efficiency from the data on the second light emitting device measured under the third condition (S223) may be performed.

In addition, deriving a maximum value of internal quantum efficiency from the data on the third light emitting device measured under the first condition (S231), deriving a maximum value of internal quantum efficiency from the data on the third light emitting device measured under the second condition (S232), and deriving a maximum value of internal quantum efficiency from the data on the third light emitting device measured under the third condition (S233) may be performed.

The recombination factor group may include a first nonradiative recombination factor, and because a first nonradiative recombination factor group may be derived from each of the plurality of data, M×N first nonradiative recombination factor groups may be derived.

For example, deriving a recombination factor group from the maximum value of the internal quantum efficiency for the first light emitting device measured under the first condition (S311), deriving a recombination factor group from the maximum value of the internal quantum efficiency for the first light emitting device measured under the second condition (S312), and deriving a recombination factor group from the maximum value of the internal quantum efficiency for the first light emitting device measured under the third condition (S313) may be performed.

In one or more embodiments, deriving a recombination factor group from the maximum value of the internal quantum efficiency for the second light emitting device measured under the first condition (S321), deriving a recombination factor group from the maximum value of the internal quantum efficiency for the second light emitting device measured under the second condition (S322), and deriving a recombination factor group from the maximum value of the internal quantum efficiency for the second light emitting device measured under the third condition (S323) may be performed. In one or more embodiments, deriving a recombination factor group from the maximum value of the internal quantum efficiency for the third light emitting device measured under the first condition (S331), deriving a recombination factor group from the maximum value of the internal quantum efficiency for the third light emitting device measured under the second condition (S332), and deriving a recombination factor group from the maximum value of the internal quantum efficiency for the third light emitting device measured under the third condition (S333) may be performed.

The recombination factor group may include the first nonradiative recombination factor, the second nonradiative recombination factor, and the emission recombination factor as described herein above. Accordingly, when all of the steps described above are performed, M×N first nonradiative recombination factors may be derived from M×N measurement data.

Referring to FIG. 3 again, when the M×N set or specific data are derived, a bulk defect factor and a surface defect factor may be distinguished and derived from each other from the M×N set or specific data, and a first defect concentration (defect concentration for the bulk defect factor) and a second defect concentration (defect concentration for the surface defect factor) may be derived by processing and/or preprocessing these data.

Hereinafter, a more detailed process of deriving a recombination factor group from the set or specific measurement data is disclosed.

The specific measurement data may include data on the injected current and the photocurrent according to the injected current as described above (see S100).

The recombination factor group may include the first nonradiative recombination factor, the emission recombination factor, and the second nonradiative recombination factor, and a recombination rate (R) may be expressed as in Equation 3.

$$R = AN + {BN}^{2} + {CN}^{3} \qquad Equation 3$$

In Equation 3, N is a carrier concentration, A is the first nonradiative recombination factor, B is the emission recombination factor, and C is the second nonradiative recombination factor. All of A, B, and C are constants.

The injected current I may be expressed as in Equation 4.

$$I = {η}_{1} ( AN + {BN}^{2} + {CN}^{3} ) \qquad Equation 4$$

In Equation 4, I is the injected current, and η₁ is an arbitrary constant.

AN is a term related to the first nonradiative recombination, BN² is a term related to the emission recombination, and CN³ is a term related to the second nonradiative recombination.

The photocurrent measured according to the injected current I may be expressed as light output power LOP, and because the light is emitted only in a case of the emission recombination, the photocurrent LOP may be expressed as in Equation 5.

$$LOP = {η}_{2} B {N}^{2} \qquad Equation 5$$

In Equation 5, η₂ is an arbitrary constant.

Internal quantum efficiency IQE is defined as:

$$IQE = ( the number of electrons that recombine with each other to emit photons ) / ( the number of injected electrons ) .$$

Injection efficiency IE may be defined as:

$$IE = ( the number of electrons that reached an active region ) / ( the number of injected electrons ) .$$

Radiative efficiency RE may be defined as:

$$RE = ( the number of electrons that recombine with each other to emit photons ) / ( the number of electrons that reached the active region ) .$$

When the injected current I is a suitably low density current, the injection efficiency IE may be close to 1 (=100%) according to definition.

The internal quantum efficiency IQE may be expressed as the product of the injection efficiency IE and the radiative efficiency RE. For example, the internal quantum efficiency IQE may be expressed as in Equation 6.

$$IQE = lE \times \frac{{BN}^{2}}{AN + {BN}^{2} + {CN}^{3}} \qquad Equation 6$$

The radiative efficiency RE may be the same as (light emitting recombination rate)/(recombination rate), and is thus expressed as in Equation 6.

A maximum value IQEMAX of the internal quantum efficiency IQE may be derived by combining Equations 3 to 6 with each other. The maximum value IQEMAX of the internal quantum efficiency IQE may be derived by Equation 7 and the Q factor.

$${IQE}_{max} = \frac{Q}{Q + 2} \qquad Equation 7$$

In order to derive (e.g., solve) Equation 7 and finally derive (e.g., derive the final) maximum value IQEMAX of the internal quantum efficiency IQE, new variables may be expressed by combining several variables described in Equations 3 to 6 with each other.

x may be expressed as in Equation 8.

$$x = \sqrt{LOP} = \sqrt{{η}_{2} B} N \qquad Equation 8$$

Because x may be derived from the measured photocurrent LOP, x is a measured value.

y may be expressed as in Equation 9.

$$y = EQE = \frac{LOP}{I} = \frac{{B η}_{2}}{{η}_{1}} \frac{1}{A / N + B + CN} \qquad Equation 9$$

Equation 9 may be derived by combining Equations 4 and 5 with each other.

In order to obtain the maximum value IQEMAX of the internal quantum efficiency IQE, the internal quantum efficiency IQE is differentiated with respect to the carrier concentration N.

According to the present embodiments, when the injected current I is the suitably low density current, the injection efficiency IE may be close to 1 (=100%) according to definition. Assuming that both (e.g., simultaneously) the current injection and a photocurrent measurement according to the injected current are performed at the suitably low density current, the carrier concentration at the maximum value IQEMAX of the internal quantum efficiency IQE may be expressed as in Equation 10.

$$\frac{dIQE}{dN} = 0 \to {N}_{0} = \sqrt{\frac{A}{C}} \qquad Equation 10$$

When the carrier concentration N has a set or specific value No, the internal quantum efficiency IQE has the maximum value IQEMAX.

When x and y are organized by combining the carrier concentration N having the set or specific value No with Equations 8 and 9, x and y are expressed as in Equations 11 and 12.

$${x}_{0} = \sqrt{{η}_{2} B} \sqrt{A / C} \qquad Equation 11$$

x₀ is an x value when the carrier concentration N has the set or specific value N₀.

$${y}_{0} = \frac{{B η}_{2}}{{η}_{1}} \frac{1}{B + 2 \sqrt{AC}} \qquad Equation 12$$

y₀ is a y value when the carrier concentration N has the set or specific value N₀.

In order to organize (e.g., simplify) Equations, when y/y₀ is organized, y/y₀ is expressed as in Equation 13.

$$\frac{y}{{y}_{0}} = \frac{B / \sqrt{AC} + 2}{B / \sqrt{AC} + ( {x}_{0} / x + x / {x}_{0} )} \qquad Equation 13$$

According to the present embodiments, x is the measured value, and in order to facilitate organization of Equation, a new variable is defined as in Equation 14. p is a normalized LOP, and may be expressed as in Equation 14. A symbol “@” indicates “at”.

$$p = \frac{LOP}{LOP @ {EQE ( = \frac{LOP}{I} )}_{MAX}} \qquad Equation 14$$

Because external quantum efficiency EQE has a maximum value EQEMAX when the carrier concentration N has the set or specific value No (see Equation 12), when Equations 8 and 11 are combined with each other, p may be expressed as a relationship with x as in Equation 15.

$${p}^{1 / 2} = x / {x}_{0} \qquad Equation 15$$

The Q factor may be expressed as in Equation 16.

$$Q = B / \sqrt{AC} \qquad Equation 16$$

When Equations 13 and 16 are combined with each other, Equation 17 is expressed as follows.

$$\frac{y}{{y}_{0}} = \frac{Q + 2}{Q + {p}^{1 / 2} + {p}^{- 1 / 2}} = \frac{EQE}{{EQE}_{MAX}} \qquad Equation 17$$

As described above, when the injected current I is the suitably low density current, the injection efficiency IE may be close to 1 (=100%) according to definition. Assuming that both (e.g., simultaneously) the current injection and the photocurrent measurement according to the injected current are performed at the suitably low density current, the internal quantum efficiency IQE may be expressed as in Equation 18 (see Equations 6, 8, 9, 11, and 16).

$$IQE = \frac{{BN}^{2}}{AN + {BN}^{2} + {CN}^{3}} = \frac{LOP / {η}_{2}}{I / {η}_{1}} = \frac{{η}_{1}}{{η}_{2}} \frac{LOP}{I} = \frac{{η}_{1}}{{η}_{2}} y = \frac{Q}{Q + {p}^{1 / 2} + {p}^{- 1 / 2}} \qquad Equation 18$$

Because a first nonradiative recombination factor A, a second nonradiative recombination factor C, and an emission recombination factor B are constants, the Q factor is a constant. When the internal quantum efficiency IQE has a maximum value, a value of x/x₀ is 1, and accordingly, the maximum value of the internal quantum efficiency IQE is expressed as follows.

$${IQE}_{MAX} = \frac{Q}{Q + 2} \qquad Equation 7$$

When Equations 17, 18, and 7 are combined with each other, the following relationship is derived.

$$\frac{{EQE}_{MAX}}{EQE} = \frac{{IQE}_{MAX}}{IQE} \qquad Equation 19$$

Accordingly, Equation 20 may be derived as follows.

$$\frac{{EQE}_{MAX}}{EQE} = \frac{Q / Q + 2}{Q / ( Q + {p}^{1 / 2} + {p}^{- 1 / 2} )} = \frac{Q + {p}^{1 / 2} + {p}^{- 1 / 2}}{Q + 2} \qquad Equation 20$$

Referring to Equation 9, it can be seen from an expression of y that y is a measured value. Accordingly, because y₀ is also a measured value, the external quantum efficiency EQE and the maximum value EQEMAX of the external quantum efficiency are measured values.

In addition, it can be seen from Equations 15 and 8 that p^{1/2}+p^{-1/2} is also a measured value.

Accordingly, when a linear regression analysis is performed in a state in which p^{1/2}+p^{-1/2} is provided as an X-axis variable and EQEMAX/EQE is provided as a Y-axis variable in Equation 20, the Q factor is derived.

When the derived Q factor and Equation 7 are combined with each other, the maximum value IQEMAX of the internal quantum efficiency IQE may be derived (see S200).

The total number of generated carriers is expressed as in Equation 21.

$$R = \frac{IE \times I}{{qV}_{active}} \qquad Equation 21$$

In Equation 21, q is a Coulomb constant and V_{active} is a volume of the active region.

When a steady state is assumed, a generation rate of carriers may be the same as a recombination rate of carriers (a rate at which the carriers recombine with each other and disappear). Accordingly, Equation 22 may be expressed.

$$\frac{dN}{dt} = G - R = \frac{IE \times I}{{qV}_{active}} - ( AN + {BN}^{2} + {CN}^{3} ) = 0 \qquad Equation 22$$

According to the present embodiments, when the injected current I is the suitably low density current, the injection efficiency IE may be close to 1 (=100%) according to definition. Assuming that both (e.g., simultaneously) the current injection and the photocurrent measurement according to the injected current are performed at the suitably low density current, Equation 23 may be derived.

$$\frac{I}{{qV}_{active}} = ( AN + {BN}^{2} + {CN}^{3} ) \qquad Equation 23$$

The internal quantum efficiency IQE in Equation 18 is expressed as in Equation 24.

$$IQE = \frac{B {N}^{2}}{A N + B {N}^{2} + {CN}^{3}} \qquad Equation 24$$

When Equations 23 and 24 are combined with each other, Equation 25 is derived.

$$N = \sqrt{\frac{IQE * I}{{BqV}_{active}}} \qquad Equation 25$$

In one or more embodiments, the internal quantum efficiency IQE may be expressed as follows.

$$\frac{IQE}{{IQE}_{MAX}} = {IQE}_{normalized} \qquad Equation 26$$

In one or more embodiments, Equation 27 is derived from Equation 19.

$${IQE}_{normalized} = \frac{IQE}{{IQE}_{MAX}} = \frac{EQE}{{EQE}_{MAX}} = {EQE}_{normalized} \qquad Equation 27$$

Accordingly, Equation 25 may be expressed as Equation 28.

$$N = \sqrt{\frac{{IQE}_{MAX}}{{BqV}_{active}}} \sqrt{{EQE}_{normalized} \times I} . \qquad Equation 28$$

In one or more embodiments, when the steady state and the suitably low current density measurement are assumed, Equation 29 is derived.

$$R = G = I / {qV}_{active} . \qquad Equation 29$$

The maximum value IQEMAX of the internal quantum efficiency IQE is derived as discussed herein above, and the volume V_{active} of the active region may be derived as the volume of the active region, and may be derived as the product of a thickness of the emitting layer EL and a size or a width of the light emitting device. I is the injected current and the measured value, and normalized external quantum efficiency EQE_{normalized} is a measured value when referring to Equations 9 and 17. Even though the emission recombination factor B is assumed to be 1×10⁻¹⁰, it does not have a significant difference (e.g., statistically significant difference) from a value derived when a cubic function nonlinear regression analysis is performed in combination with Equation 3. Referring to Equation 29, the recombination rate R is derived. Referring to Equation 3, the nonlinear regression analysis may be performed in a state in which the carrier concentration N is provided as an X-axis variable and the recombination rate R is provided as a Y-axis variable.

$$R = AN + {BN}^{2} + {CN}^{3} \qquad Equation 3$$

Accordingly, when Equation 28, Equation 29, and Equation 3 are combined with each other, the first nonradiative recombination factor A and the second nonradiative recombination factor C may be derived (see S300).

Accordingly, the first nonradiative recombination factor A, the second nonradiative recombination factor C, and the emission recombination factor B included in the recombination factor group may be derived according to the present embodiments through the above-described process.

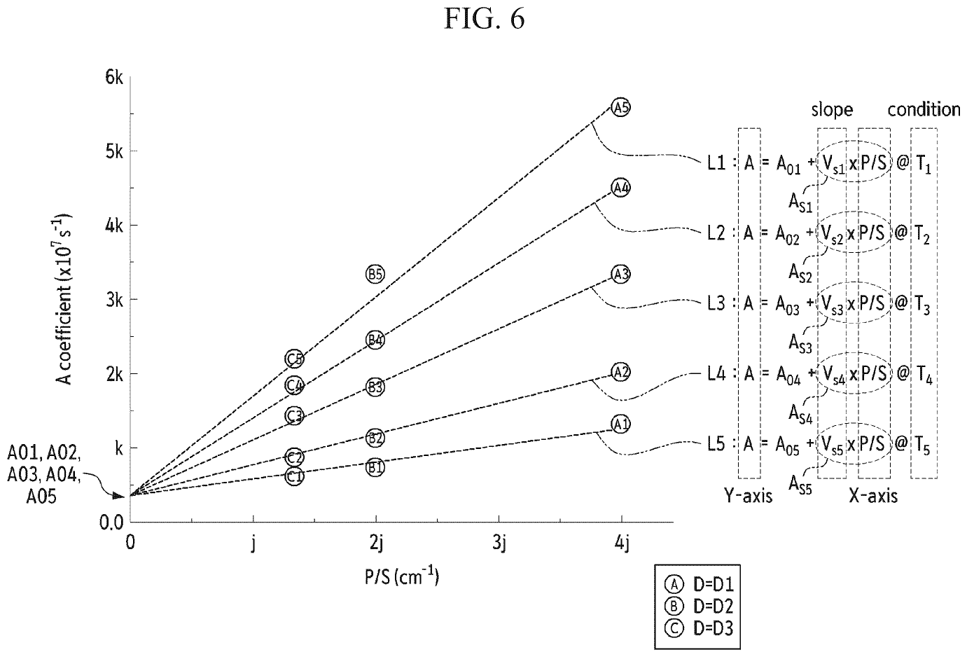

FIG. 6 is a view for describing distinguishing a bulk defect factor and a surface defect factor from each other.

When the above-described process according to the present embodiments is repeated (e.g., among N light emitting devices), M×N recombination factor groups may be derived by injecting the current into each of the N light emitting devices having the different sizes at the M different temperatures and measuring the photocurrent according to the injected current. Accordingly, M×N first nonradiative recombination factors (A coefficients) may be derived.

The first nonradiative recombination factor A may be expressed as in Equation 30.

$$A = {A}_{0} + {A}_{S} \qquad Equation 30$$

A₀ is a bulk defect factor, and Aₛ is a surface defect factor.

Equation 30 is expressed in more detail as in Equation 31.

$$A = {A}_{0} + {v}_{s} {A}_{S} \qquad Equation 31$$

Equation 31 is expressed in more detail as in Equation 32 in consideration of a unit.

$$A = {A}_{0} + {v}_{s} \frac{P}{S} \qquad Equation 32$$

Referring to FIG. 6, for example, assuming that M is 5 and N is 3, data measured at five temperatures T1, T2, T3, T4, and T5 for each of three different light emitting devices A, B, and C may be processed. Accordingly, when the above-described process is repeated (e.g., for each light emitting device at each temperature), fifteen first nonradiative recombination factors A are derived. However, embodiments of the present disclosure are not limited thereto, and M may be a natural number of 2 or more and N may be a natural number of 2 or more.

For each of three light emitting devices A, B, and C having different sizes (e.g., different diameters), data on the first nonradiative recombination factors A may be extracted at a first temperature T1, a second temperature T2, a third temperature T3, a fourth temperature T4, and a fifth temperature T5. Accordingly, data on fifteen (3×5) first nonradiative recombination factors A may be extracted.

In the three light emitting devices A, B, and C having the different sizes, assuming that the light emitting devices each have a spherical shape, a first light emitting device A may have a first diameter D1, a second light emitting device B may have a second diameter D2, and a third light emitting device C may have a third diameter D3. The first diameter D1 may be smaller than the second diameter D2, and the second diameter D2 may be smaller than the third diameter D3. Because a diameter is twice the radius, a first radius is derived from the first diameter D1, a second radius is derived from the second diameter D2, and a third radius is derived from the third diameter D3.

P is a perimeter length in a cross section including the center of a sphere (i.e. 2 πr), and S is a cross sectional area including the center of the sphere (i.e. area of mesa) (i.e. πr²) of the cross section including the center of the sphere.

In the data on the fifteen first nonradiative recombination factors A according to one or more embodiments, a linear regression analysis may be performed in a state in which P/S is provided as an X-axis variable and the data on the first nonradiative recombination factor A is provided as Y-axis variables.

Five linear graphs L1, L2, L3, L4, and L5 may be derived by performing the linear regression analysis on data derived at the same temperature among the plurality of data points.

The linear regression analysis may be performed so that Equation 1 is derived.

$$Y = A X + B . \qquad Equation 1$$

In one or more embodiments, the linear regression analysis is performed on the data from the three light emitting devices having the different sizes. When the linear regression analysis is performed on at least two light emitting devices having different sizes, a linear graph may be derived. However, in some embodiments, a method may be used for at least three light emitting devices having the different sizes, which may improve the accuracy of the linear regression analysis.

When a first nonradiative recombination factor for the first light emitting device A measured at the first temperature T1, a first nonradiative recombination factor for the second light emitting device B measured at the first temperature T1, and a first nonradiative recombination factor for the third light emitting device C measured at the first temperature T1 are synthesized, a first linear graph L1 may be derived.

When a first nonradiative recombination factor for the first light emitting device A measured at the second temperature T2, a first nonradiative recombination factor for the second light emitting device B measured at the second temperature T2, and a first nonradiative recombination factor for the third light emitting device C measured at the second temperature T2 are synthesized, a second linear graph L2 may be derived.

When a first nonradiative recombination factor for the first light emitting device A measured at the third temperature T3, a first nonradiative recombination factor for the second light emitting device B measured at the third temperature T3, and a first nonradiative recombination factor for the third light emitting device C measured at the third temperature T3 are synthesized, a third linear graph L3 may be derived.

When a first nonradiative recombination factor for the first light emitting device A measured at the fourth temperature T4, a first nonradiative recombination factor for the second light emitting device B measured at the fourth temperature T4, and a first nonradiative recombination factor for the third light emitting device C measured at the fourth temperature T4 are synthesized, a fourth linear graph L4 may be derived.

When a first nonradiative recombination factor for the first light emitting device A measured at the fifth temperature T5, a first nonradiative recombination factor for the second light emitting device B measured at the fifth temperature T5, and a first nonradiative recombination factor for the third light emitting device C measured at the fifth temperature T5 are synthesized, a fifth linear graph L5 may be derived.

Referring to Equation 32, five bulk defect factors A01, A02, A03, A04, and A05 and fifteen surface defect factors may be derived from each of the five linear graphs L1, L2, L3, L4, and L5.

The five bulk defect factors A01, A02, A03, A04, and A05 may be Y-intercepts of each of the five linear graphs L1, L2, L3, L4, and L5.

Referring to Equation 30, when bulk defect factor values corresponding to each temperature are subtracted from the data on the fifteen first nonradiative recombination factors A, data on fifteen surface defect factors may be extracted. The fifteen surface defect factors may include three surface defect factors AS1 at the first temperature T1, three surface defect factors AS2 at the second temperature T2, three surface defect factors AS3 at the third temperature T3, three surface defect factors AS4 at the fourth temperature T4, and three surface defect factors AS5 at the fifth temperature T5.

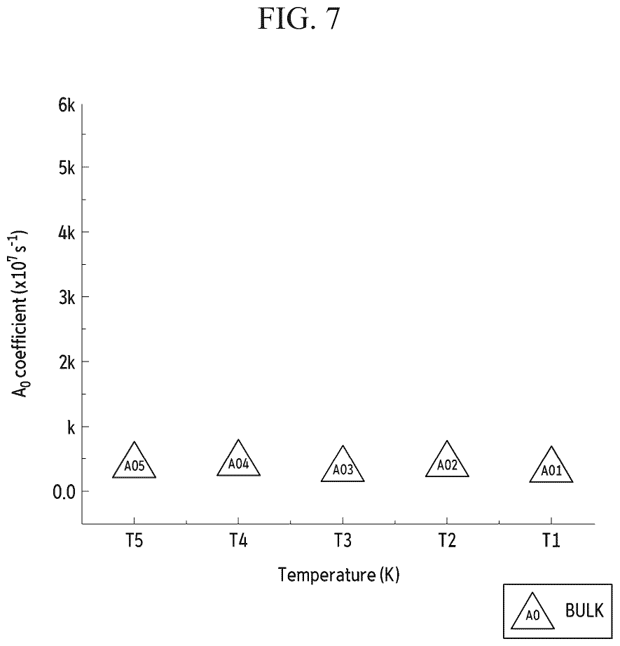

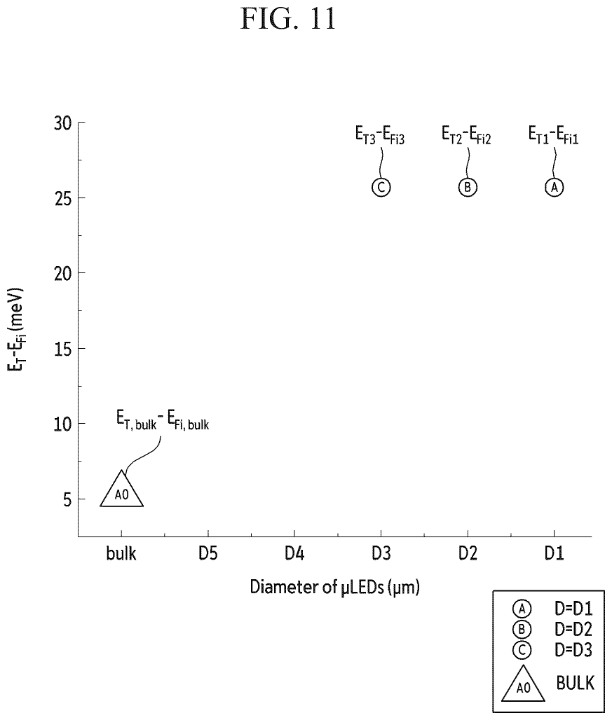

FIGS. 7 to 13 are views for describing deriving a defect concentration for the bulk defect factor and a defect concentration for the surface defect factor.

For a nonlinear regression analysis to be described later, Equation 33 is disclosed.

$${τ}_{nr} = {τ}_{0} ( 1 + cosh \frac{{E}_{T} - {E}_{Fi}}{kT} ) . \qquad Equation 33$$

Tₙᵣ is a non-radiative lifetime, and corresponds to a reciprocal of each of defect factors including the bulk defect factor A₀ and the surface defect factor As.

E_{T} corresponds to an energy trap level of each of the defects, and Eri is an intrinsic Fermi level. k is a Boltzmann constant, and T is temperature.

T₀ is a minority carrier lifetime, and has a relationship of Equation 34 with a defect concentration NT for the defect factor. A relative value of the defect concentration to the bulk defect factor A₀ may be the first defect concentration, and a relative value of the defect concentration to the surface defect factor As may be the second defect concentration.

$${τ}_{0} = {( {N}_{T} \cdot {v}_{th} \cdot σ )}^{- 1} . \qquad Equation 34$$

Accordingly, when a nonlinear regression analysis is performed in a state in which the reciprocal of the defect factor including the bulk defect factor A₀ and the surface defect factor Aₛ is provided as a Y-axis variable and five different temperatures are provided as X-axis variables, To is derived, from which the relative values of the defect concentrations may be compared with each other.

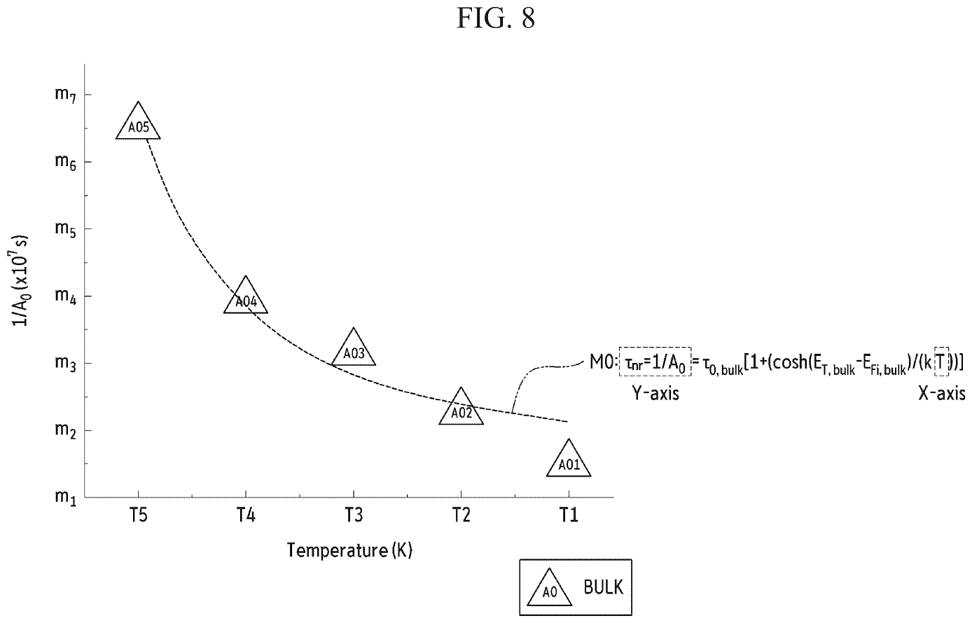

Referring to FIGS. 7 and 8, a nonlinear regression analysis may be performed on five bulk defect factors A₀: A01, A02, A03, A04, and A05 according to one or more embodiments in a state in which five different temperatures T1, T2, T3, T4, and T5 are provided as X-axis variables and reciprocal data of the five bulk defect factors A₀: A01, A02, A03, A04, and A05 are provided as Y-axis variables.

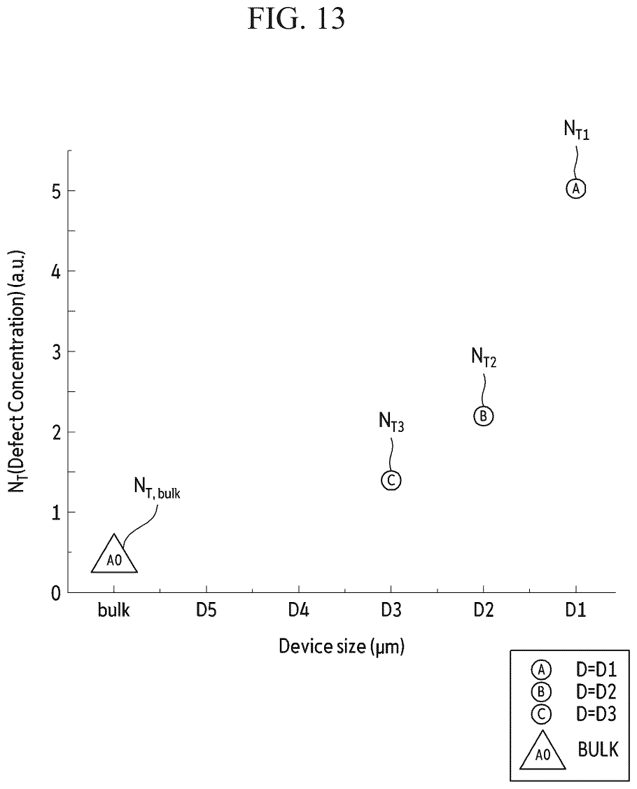

In a process of deriving minority carrier lifetime data on the bulk defect factors A₀, the bulk defect factors A₀ may be substantially the same as each other at the five different temperatures (see FIG. 7). In the process of deriving the minority carrier lifetime data on the bulk defect factors A₀, values of the first defect concentrations due to the bulk defect factors A₀ may be assumed to be substantially the same as each other regardless of sizes of the light emitting devices (see FIG. 13).

One nonlinear graph may be derived from reciprocal data of a plurality of bulk defect factors A₀.

The nonlinear regression analysis may be performed so that Equation 2 is derived.

$$Y = C \times [ 1 + cosh ( D / X ) ] . \qquad Equation 2$$

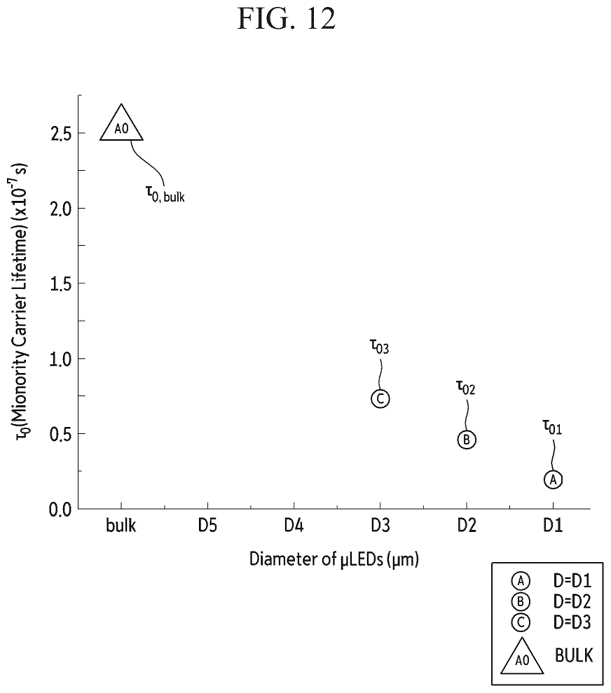

C derived from a nonlinear graph M₀ for the bulk defect factor A₀ is a minority carrier lifetime for the bulk defect factor A₀, and its reciprocal may be considered as a relative value of the first defect concentration (see FIG. 12). C may have an inverse proportional relationship with the relative value of the first defect concentration.

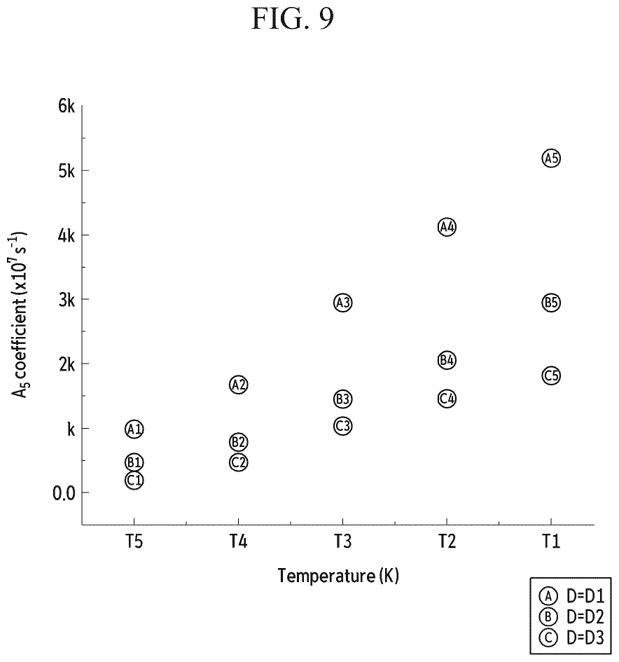

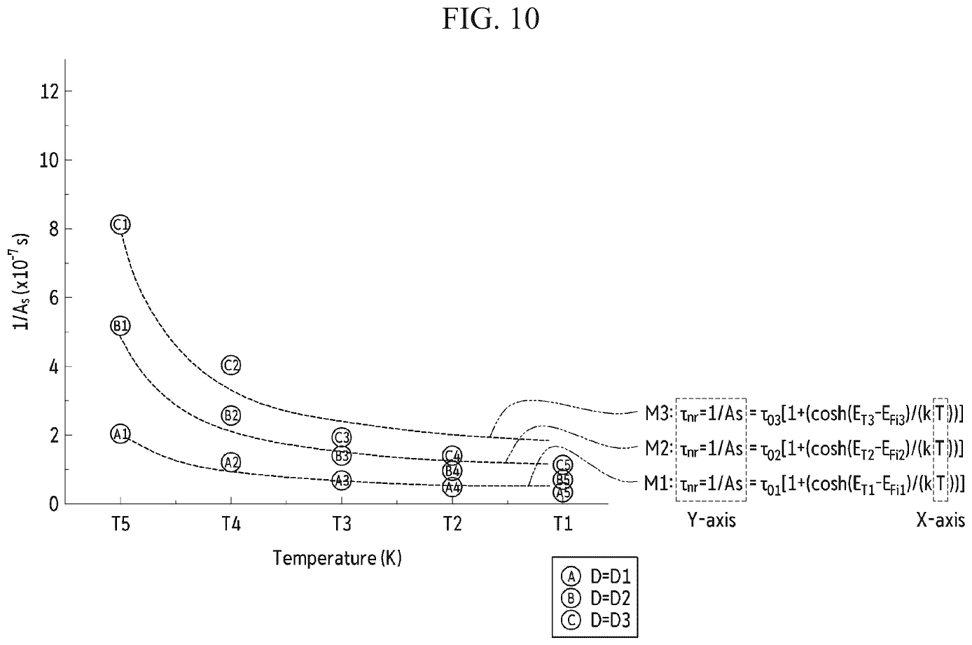

Referring to FIGS. 9 and 10, a nonlinear regression analysis may be performed on data on fifteen surface defect factors Aₛ according to one or more embodiments in a state in which five different temperatures T1, T2, T3, T4, and T5 are provided as X-axis variables and reciprocal data of the fifteen surface defect factors Aₛ are provided as Y-axis variables.

Three nonlinear graphs may be derived by performing a nonlinear regression analysis on data of light emitting devices having the same size among the plurality of data.

The nonlinear regression analysis may be performed so that Equation 2 is derived.

$$Y = C \times [ 1 + cosh ( D / X ) ] \qquad Equation 2$$

C derived from a first nonlinear graph M1 may be a minority carrier lifetime for a first surface defect factor derived from the first light emitting device. C derived from a second nonlinear graph M2 may be a minority carrier lifetime for a second surface defect factor derived from the second light emitting device. C derived from a third nonlinear graph M3 may be a minority carrier lifetime for a third surface defect factor derived from the third light emitting device (see FIG. 12). C may have an inverse proportional relationship with a relative value of each of second defect concentrations.

A reciprocal of the first surface defect factor may be considered as a relative value of the second defect concentration of the first light emitting device. A reciprocal of the second surface defect factor may be considered as a relative value of the second defect concentration of the second light emitting device. A reciprocal of the third surface defect factor may be considered as a relative value of the second defect concentration of the third light emitting device.

Referring to FIG. 13, when sizes of three light emitting devices are provided as X-axis variables and three second defect concentration relative values and one first defect concentration relative value are provided as Y-axis variables, it may be confirmed that the second defect concentration relative value gradually increases as the diameter of the light emitting device decreases toward the first diameter.

When the method for analyzing defects of light emitting devices according to one or more embodiments is used, it may be confirmed that a ratio of a defect concentration for the surface defect increases as the size of the light emitting device decreases. Accordingly, both (e.g., simultaneously) ratios of the surface defects and the bulk defects may be quantified, and the method provided in the present disclosure may be used to solve a problem of a light emitting efficiency decreasing as the size of the light emitting device decreases. For example, a passivation layer may be utilized in an etching process in order reduce a surface defect aspect as the size of the light emitting device decreases.

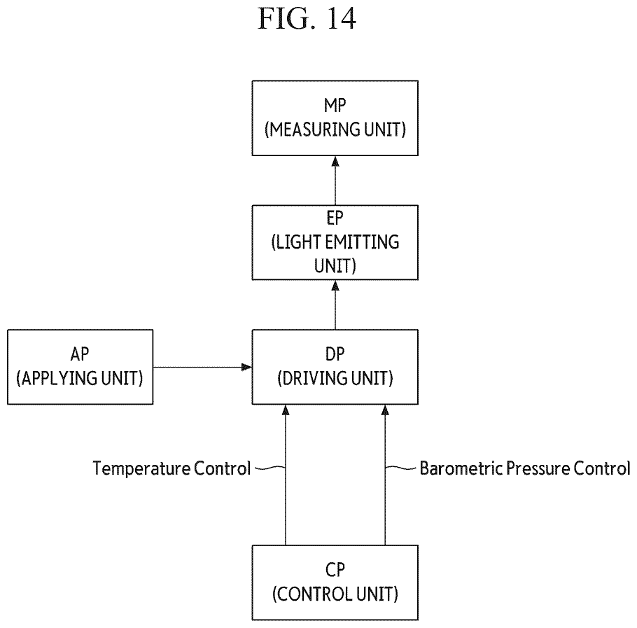

FIG. 14 is a block diagram illustrating a measuring device that may be used in an operation and/or a process of measuring a current injected into a light emitting device and a photocurrent according to the injected current.

Referring to FIG. 14, in the system for analyzing defects of light emitting devices, the data preprocessing unit performing the operation of injecting the current into each of the N light emitting devices having the different sizes at the M different temperatures, measuring the photocurrent according to the injected current, and deriving the plurality of data may include a driving unit DP, a control unit CP, an applying unit AP, a light emitting unit EP, a measuring unit MP, and/or the like.

The driving unit DP is a system in which measurement is performed, and may include a window for measurement and a measuring system.

The control unit CP may control a temperature and a vacuum state of the driving unit DP (e.g., Temperature Control and Barometric Pressure Control), and the temperature may be controlled or selected by an injection speed (or amount) of liquid nitrogen, a heating stage, and/or the like. The vacuum state may be controlled or selected by absorbing a gas existing in the driving unit DP, and to this end, the control unit CP may control a motor and/or a valve. In one or more embodiments, the control unit CP may maintain a suitably low vacuum state of the driving unit DP at an atmospheric pressure of about 0.01 torr. In one or more embodiments, the control unit CP may maintain a suitably low temperature state of the driving unit DP at a temperature of 100 K to 300 K.

The measuring unit MP may measure light and/or a photocurrent emitted from the light emitting unit EP when a current and/or a voltage are applied to the light emitting unit EP by the applying unit AP. In one or more embodiments, the measuring unit MP may be implemented in the form of an integrating sphere. The measuring unit MP implemented in the form of the integrating sphere may cover the driving unit DP. An optical fiber may be connected to the integrating sphere to transmit the light emitted from the light emitting unit EP.

The light emitting unit EP may be connected to the measuring unit MP, and the current and/or the voltage may be applied to the light emitting unit EP. An inner portion of the integrating sphere may be coated with a total reflection inducing material. When the current and/or the voltage are applied to the light emitting unit EP, the light emitted from the light emitting unit EP is totally reflected in the integrating sphere and then transmitted to the measuring unit MP through the optical fiber, and the measuring unit MP may measure all of the emitted light.

The measuring unit MP may further include an amplifier amplifying a measured photocurrent signal in order to improve measuring accuracy of the emitted light. In one or more embodiments, the measuring unit MP may further include a spectrometer and/or the like in order to measure the photocurrent from a spectrum of the light.

Although embodiments of the present disclosure have been described above with reference to the accompanying drawings, it will be understood by those having ordinary skill in the technical field to which the disclosure belongs that the disclosure may be practiced in other suitable forms without altering the technical idea or essential features of the disclosure. It should therefore be understood that the embodiments described above are examples in all respects and are not intended to be limiting, and that various modifications to the disclosed embodiments, as well as other example embodiments, are intended to be included within the spirit and scope of the present disclosure as defined in the appended claims, and their equivalents.

What is claimed is:

1. A method for analyzing defects of light emitting devices, the method comprising:
injecting a current into each of N light emitting devices having different sizes at M different temperatures, measuring a photocurrent according to the injected current, and deriving a plurality of data;
distinguishing and deriving a bulk defect factor and M×N surface defect factors from each other from the plurality of data; and
deriving a first defect concentration for the bulk defect factor and N second defect concentrations for the M×N surface defect factors,
wherein M is a natural number of 2 or more, and
N is a natural number of 2 or more.

2. The method of claim 1, wherein N is a natural number of 3 or more.

3. The method of claim 1, further comprising deriving a plurality of internal quantum efficiency maximum values from the plurality of data.

4. The method of claim 1, further comprising deriving a plurality of recombination factor groups from the plurality of data.

5. The method of claim 4, further comprising deriving M×N recombination factor groups from the plurality of data,
wherein the recombination factor group comprises a first nonradiative recombination factor, an emission recombination factor, and a second nonradiative recombination factor.

6. The method of claim 5, wherein the first nonradiative recombination factor is defined as a sum of the bulk defect factor and the surface defect factor.

7. The method of claim 5, wherein the distinguishing and the deriving of the bulk defect factor and the M×N surface defect factors from each other from the plurality of data comprises performing a linear regression analysis in a state in which sizes of the N light emitting devices are X-axis variables and M×N first nonradiative recombination factors are Y-axis variables.

8. A system for analyzing defects of light emitting devices, the system comprising:
a data preprocessing unit to perform an operation of injecting a current into each of N light emitting devices having different sizes at M different temperatures, measuring a photocurrent according to the injected current, and deriving a plurality of data;
a first analysis unit to perform an operation of distinguishing and deriving a bulk defect factor and M×N surface defect factors from each other from the plurality of data; and
a second analysis unit to perform an operation of deriving a first defect concentration for the bulk defect factor and N second defect concentrations for the M×N surface defect factors,
wherein M is a natural number of 2 or more, and
N is a natural number of 2 or more.

9. The system of claim 8, wherein the data preprocessing unit comprises a measuring unit comprising an integrating sphere coated with a total reflection inducing material, and an optical fiber connected to the integrating sphere to transmit light generated from the light emitting device, and
the measuring unit is to measure the photocurrent from the light transmitted from the optical fiber.

10. The system of claim 8, wherein the data preprocessing unit comprises a measuring unit comprising an optical fiber to transmit light generated from the light emitting device, and
the measuring unit is to measure the photocurrent by measuring a spectrum of the light transmitted from the optical fiber.
